(19) United States
(12) Patent Application Publication
(10) Pub. No.: US 2002/0089009 A1
(43) Pub. Date: Jul. 11, 2002

(54) Capacitance dielectric film and method of manufacturing the same

(75) Inventor: Hiroyuki Kitamura, Tokyo (JP)

Correspondence Address: SUGHRUE, MION, ZINN,, MACPEAK & SEAS, 2100 Pennsylvania Avenue, N.W., Washington, DC, 20037, US

(73) Assignee: NEC CORPORATION

(21) Appl. No.: 10/000,324

(22) Filed: Dec. 4, 2001

(30) Foreign Application Priority Data
Dec. 7, 2000 (JP) 373117/2000

(51) Int. Cl. H01L 21/8242; H01L 27/108; H01L 29/76

(52) U.S. Cl. 257/306; 438/244; 438/253; 257/308; 438/399; 257/309; 438/255; 257/310

(57) ABSTRACT

A semiconductor device providing a substrate, an insulating layer disposed on the substrate and a lower capacitance electrode disposed on the insulating layer. The lower capacitance electrode includes a polysilicon layer and a metal nitride silicide layer and a tantalum oxide layer disposed on the lower capacitance electrode. An upper capacitance electrode, formed from a metal nitride, is disposed on the tantalum oxide layer.

### BACKGROUND OF THE INVENTION

1. Field of the Invention

The present invention generally relates to a semiconductor device having a capacitance and particularly, but not limited to, a capacitance having a tantalum oxide layer as a dielectric layer, and a method of manufacturing the device. The present application is based on Japanese Patent Application No. 373117/2000, which is incorporated herein by reference.

2. Description of the Related Art

When a tantalum oxide (Ta₂O₅) film grows on a silicon layer and is then oxidized, a silicon oxide (SiO₂) film grows at boundary between the tantalum oxide film and the silicon layer. Thus, an effective specific inductive capacity decreases.

When manufacturing a DRAM capacitance, a cylinder electrode covered with a metal film can prevent the silicon oxide film from growing. However, it is difficult to form a minute metal cylinder electrode by dry etching or a CMP method (a chemical mechanical polishing method). Hence, a polysilicon electrode is used since it is easily processed, and a silicide layer is selectively formed on its surface. However, because the stacked structure of the silicide and silicon has a low thermal stability, when a tantalum oxide film grows on the polysilicon electrode and is then oxidized, silicon atoms are supplied from the polysilicon layer. Thus, silicon atoms are deposited between the silicide layer and the tantalum oxide film, and in and on the tantalum oxide film. The silicon atoms cause a leakage current between the silicide layer as a lower electrode and an upper electrode.

An embodiment of the present invention provides a semiconductor device with high thermal stability and a small leakage current value, and a method of manufacturing the device.

### SUMMARY OF THE INVENTION

A first exemplary embodiment of the present invention provides a semiconductor device comprising a substrate, a first insulating layer disposed on the substrate and a first capacitance electrode disposed on the first insulating layer. The first capacitance electrode comprises a polysilicon layer and a metal nitride silicide layer disposed on the polysilicon layer and a tantalum oxide layer disposed on the first capacitance electrode. The first embodiment of the present invention further comprises a second capacitance electrode disposed on the tantalum oxide layer, and the second capacitance electrode comprises a metal nitride layer.

A second exemplary embodiment of the present invention provides a method of manufacturing a semiconductor device. The manufacturing method comprises forming a first insulating layer on a substrate, forming an amorphous silicon layer on the first insulating layer and forming a metal layer on the amorphous silicon layer. The method further comprises heating the substrate so as to convert the metal layer into a nitride silicide layer. After the substrate is is heated, a tantalum oxide layer is formed on the nitride silicide layer, and an upper capacitance electrode is formed on the tantalum oxide layer.

### BRIEF DESCRIPTION OF THE DRAWINGS

The above and other aspects, advantages and features of the present invention will be more apparent from the following description taken in conjunction with the accompanying drawings, in which:

FIG. 1 is a cross-sectional view of a semiconductor device of an exemplary embodiment of the present invention;

FIGS. 2A to 2H show an exemplary method of manufacturing a capacitance element region shown in FIG. 1; and

FIG. 3 shows current-voltage characteristics of cylinder-type capacitors, in order to compare with the related art and the exemplary embodiment of the present invention.

### BRIEF DESCRIPTION OF THE INVENTION

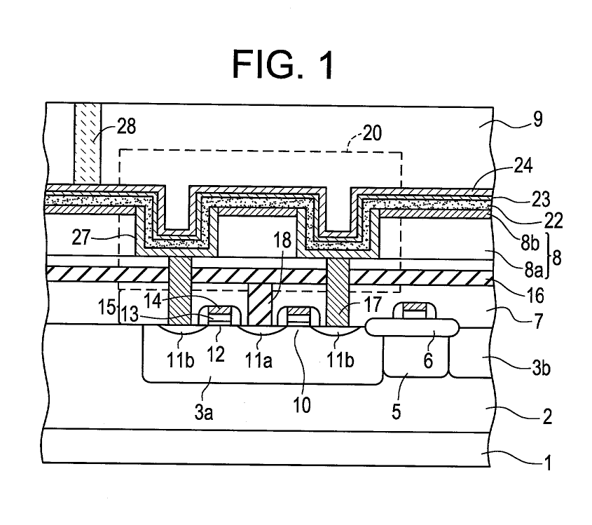

An exemplary embodiment of the present invention will now be described with reference to FIGS. 1 to 3. Note that each component of the exemplary embodiment is similar to the conventional example described above and will be denoted by using the same nomenclature. Therefore, a detailed description thereof will not be provided below.

As shown in FIG. 1, according to an exemplary embodiment of the present invention, a cell portion of a DRAM has the following structure. An N-well 2 is provided on a surface of a p-type silicon substrate 1, a first p-well 3a is provided on the surface of the N-well 2, and an N-type isolation region 5 is provided on the periphery of the first p-well 3a. Besides the first p-well 3a, the N-type isolation region 5, and the periphery thereof, a second p-well 3b is formed on the surface of the N-well 2. The first p-well 3a and the second p-well 3b are subjected to element isolation such that they isolated from each other by the N-type isolation region 5 and a field oxide film 6 formed on its surface. On the surface of the first p-well 3a, a transistor 10 that comprises a memory cell is formed in an active region that is subjected to the element isolation by the field oxide film 6. In FIG. 1, a pair of memory cells is shown. The transistor 10 is comprised of a gate insulating film 12 provided on the surface of the first p-well 3a. A gate electrode 15 is provided through lamination of a polycrystalline silicon film 13 that is formed above the surface of the first p-well 3a with the gate insulating film 12 interposed therebetween and a silicide film 14. The transistor 10 is covered with a first interlayer insulating film 7. In the first interlayer insulating film 7, a contact hole 18 is made that reaches a source and drain region 11a that is shared by a pair of transistors 10. A word line and a bit line 16 are connected to the source/drain region 11a through the contact hole 18 and are covered with a second interlayer insulating film 8. In FIG. 1, the bit line 16 does not contact the plug 17, and bit line 16 and plug 17 are physically separate from each other.

A capacitance element region 20 is provided on the second interlayer insulating film 8. The capacitance element region is a stacked type and is composed of a capacitance lower electrode 27, a tantalum oxide film 22 as a capacitance insulating film, and a capacitance upper electrode 23. The capacitance element region passes through the first interlayer insulating film 7 and the second interlayer insulating film 8 in order to be connected to the other N-type source and drain regions 11b corresponding to the pair of transistors 10, respectively. The capacitance upper electrode 23 is formed continuously, so that each capacitance element part of the pair of memory cells is brought into a sharable state. The capacitance upper electrode 23 extends over the surface of the second interlayer insulating film 8, and a capacitance upper electrode 24 is formed thereon that serves as a lead-out portion for connection with an upper-layer wire. The capacitance element part 20 is covered with a third interlayer insulating film 9. A contact plug 28 connects the capacitance upper electrode 24 to an upper wiring disposed on the third interlayer insulating film 9.

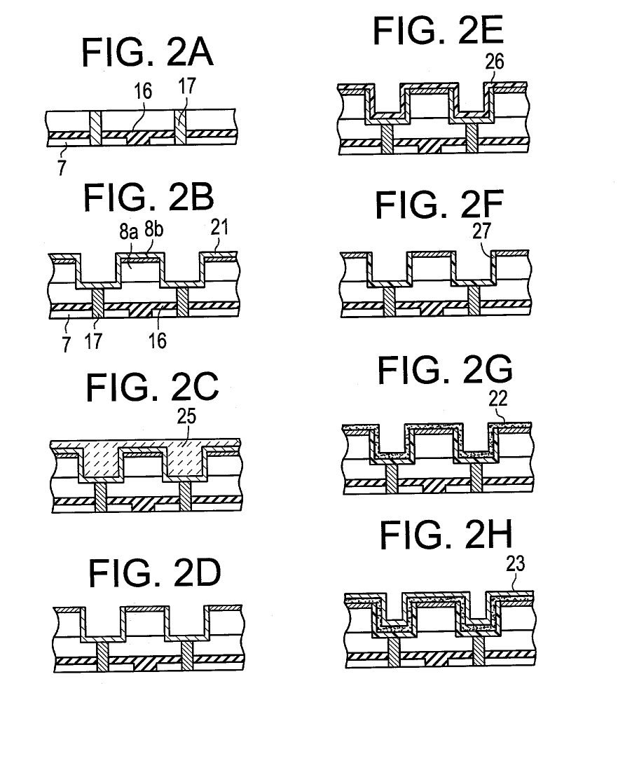

FIGS. 2A to 2H illustrate the process of manufacturing the capacitance element region 20 shown in FIG. 1.

Referring to FIG. 2A, the first interlayer insulating film 7, the word line and the bit line 16, and the rest of the first interlayer insulating film 7 are formed over the silicon substrate. In this film, a capacitance contact hole is made. The capacitance contact hole is filled with a metal film made of phosphorus-doped amorphous silicon, tungsten or similar materials, and thus a plug 17 is formed.

The metal film is left only in a portion corresponding to the plug by etchback of the silicon substrate obtained as shown in FIG. 2A. Referring to FIG. 2B, on top thereof, the interlayer insulating films 8 (8a and 8b) are allowed to grow. Subsequently, holes for stack electrode formation is made through the interlayer insulating films 8 (8a and 8b). The holes for stack electrode formation are made coincident with the capacitance contact holes. A phosphorus-doped amorphous silicon film 21 for a stack electrode is formed over the whole surface of the substrate including the holes for stack electrode formation.

Referring to FIG. 2C, the interior surfaces of the holes for stack electrode formation are filled with a silicon oxide film 25 by a spin coating method.

Referring to FIG. 2D, the amorphous silicon film 21 for stack electrode formation is left only in the interior surfaces of the holes for stack electrode formation by etchback. Next, the remaining silicon oxide film 25 is etched with a dilute hydrofluoric acid aqueous solution.

Referring to FIG. 2E, a titanium film 26 is formed over the whole surface of the silicon substrate, including the interior surfaces of the holes for stack electrode formation, as well as the portions of the silicon substrate between the holes for stack formation. A tungsten film or a tantalum film can be used instead of the titanium film 26.

Referring to FIG. 2F, solid phase reaction (alloy reaction) is caused by heat treatment (for example, 700° C.), so that the whole of the titanium film 26 in the electrode portion is converted into a titanium nitride silicide film 27. An excess of the film is removed with a hydrogen peroxide solution.

Referring to FIG. 2G, a capacitance insulating film 22 formed of a tantalum oxide (Ta₂O₅) film is formed over the whole surface of the substrate by a low pressure chemical vapor growth method (a LPCVD method) using Ta(OC₂H₅)₅ and O₂. The capacitance insulating film 22 is heat-treated, for example, with oxygen gas at 800° C., and the tantalum oxide film is oxidized in order to be crystallized.

Referring to FIG. 2H, for example, using titanium tetrachloride (TiCl₄) and ammonia (NH₃), an electrode 23 of a titanium nitride (TiN) film is formed on the capacitance insulating film 22 by a chemical vapor growth method (a CVD method).

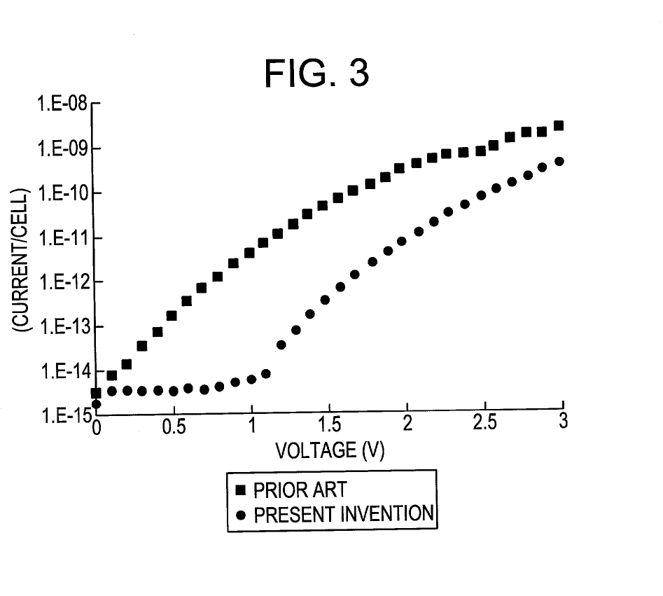

Referring to FIG. 3, the current-voltage characteristics of cylinder-type capacitors manufactured according to the present invention and the conventional technique are shown.

Ten thousand pieces of stacks were formed in parallel. One ten-thousandth of a current value to be obtained is the current value per capacitor. According to the conventional technique, a leakage current value at a voltage of 1V is 5×10⁻¹⁵ amperes per cell. On the other hand, according to the present invention, the cylinder electrode has high thermal stability and growth of the silicon film does not occur in the steps for manufacturing the capacitor. Hence, the leakage current was reduced and the leakage current value at a voltage of 1V was 1×10⁻¹⁵ amperes per cell, i.e., was reduced by one-fifth.

According to the present invention, a semiconductor device can be obtained that has high thermal stability and a small leakage current value.

The present invention is not limited to the above embodiments, and it is contemplated that numerous modifications may be made without departing from the spirit and scope of the invention. The capacitance structure, as described above with reference to the figures, is a merely an exemplary embodiment of the invention, and the scope of the invention is not limited to these particular embodiments. Accordingly, other structural configurations may be used, without departing from the spirit and scope of the invention.

What is claimed is:

1. A semiconductor device comprising:
a substrate,
a first insulating layer disposed on the substrate,
a first capacitance electrode disposed on the first insulating layer, the first capacitance electrode comprising a polysilicon layer and a metal nitride silicide layer disposed on the polysilicon layer,
a tantalum oxide layer disposed on the first capacitance electrode,
a second capacitance electrode disposed on the tantalum oxide layer.

2. The semiconductor device as claimed in claim 1, further comprising:
a first cavity formed in the first insulating layer, and
wherein the first capacitance electrode is disposed at least on an inner wall of the first cavity and a bottom surface of the first cavity.

3. The semiconductor device as claimed in claim 2, wherein the tantalum oxide layer is disposed on the first capacitance electrode and on a surface of the first insulating layer surrounding the first cavity.

4. The semiconductor device as claimed in claim 3, further comprising:
a first word line and a second word line disposed on the substrate,
a data line disposed perpendicular to the first word line,
a first contact plug connecting the data line to the substrate, the first contact plug disposed between the first word line and the second word line,
a second contact plug connecting the first capacitance electrode to the substrate, and
wherein the second contact plug is disposed on an opposite side of the first contact plug, putting the first word line between the first contact plug and the second contact plug.

5. The semiconductor device as claimed in claim 4, wherein the first insulating layer is disposed on the first word line and the second word line, and
wherein the first cavity is arranged on the second contact plug.

6. The semiconductor device as claimed in claim 5, further comprising:
a third contact plug connecting the first capacitance electrode to the substrate, and
wherein the third contact plug is disposed on an opposite side of the first contact plug, putting the second word line between the first contact plug and the third contact plug.

7. The semiconductor device as claimed in claim 6, further comprising:
a second cavity arranged on the third contact plug, and
wherein the first capacitance electrode comprises a first part of the first capacitance electrode and a second part of the first capacitance electrode, and
wherein the second contact plug connects the first part of the first capacitance electrode to the substrate, and the third contact plug connects the second part of the first capacitance electrode to the substrate.

8. The semiconductor device as claimed in claim 7, further comprising:
a second insulating layer on the second capacitance electrode,
a fourth contact plug disposed into the second insulating layer, and connected to the second capacitance electrode.

9. The semiconductor device as claimed in claim 1, wherein the metal nitride silicide layer comprises a titanium nitride silicide.

10. The semiconductor device as claimed in claim 1, wherein the second capacitance electrode comprises a metal nitride layer.

11. The semiconductor device as claimed in claim 10, wherein the metal nitride layer comprises a titanium nitride.

12. A method of manufacturing a semiconductor device comprising:
forming a first insulating layer on a substrate,
forming an amorphous silicon layer on the first insulating layer,
forming a metal layer on the amorphous silicon layer,
heating the substrate so as to convert the metal layer into a nitride silicide layer,
forming a tantalum oxide layer on the nitride silicide layer, and
forming an upper capacitance electrode.

13. The method of manufacturing a semiconductor device as claimed in claim 12, further comprising:
forming a first cavity in the first insulating layer before the forming the amorphous silicon layer,
forming a cover layer on the amorphous silicon layer,
removing the cover layer and the amorphous silicon layer on an upper surface of the first insulating layer to retain the cover layer and the amorphous silicon layer on an inner wall of the cavity and on a bottom surface of the cavity, and
removing the cover layer buried in the first cavity so as to retain the amorphous silicon layer on the inner surface of the first cavity.

14. The method of manufacturing a semiconductor device as claimed in claim 13, wherein the removing the cover layer buried in the first cavity is performed by an etching method, and
wherein an etching speed of the cover layer is greater than an etching speed of the first insulating layer.

15. The method of manufacturing a semiconductor device as claimed in claim 13, wherein the tantalum oxide layer is formed by a low pressure chemical vapor deposition method using Ta(OC₂H₅)₅O₂.

16. The method of manufacturing a semiconductor device as claimed in claim 13, wherein the upper capacitance electrode is made of a titanium nitride and the titanium nitride is formed by a chemical vapor deposition method using at least TiCl₄ and NH₃.

17. The method of manufacturing a semiconductor device as claimed in claim 13, further comprising annealing the tantalum oxide layer under an oxygen gas atmosphere.

18. The method of manufacturing a semiconductor device as claimed in claim 17, wherein the amorphous silicon layer comprises a phosphorus-doped silicon.

19. The method of manufacturing a semiconductor device as claimed in claim 17, further comprising:
forming a first word line and a second word line on the substrate,
forming a data line perpendicular to the first word line,
forming a first contact plug connecting the data line to the substrate, the first contact plug disposed between the first word line and the second word line,
forming a second contact plug connecting the amorphous silicon layer to the substrate, the second contact plug disposed on an opposite side of the first contact plug against the first word line, and
forming a third contact plug connecting the amorphous silicon layer to the substrate, the third contact plug disposed on an opposite side of the first contact plug against the second word line.

20. The method of manufacturing a semiconductor device as claimed in claim 19, further comprising:
forming a second cavity in the first insulating layer, and
wherein the amorphous silicon layer comprises a first part of the amorphous silicon layer disposed on the first cavity, and a second part of the amorphous silicon layer disposed on the second cavity.

21. The method of manufacturing a semiconductor device as claimed in claim 20, further comprising the removal of at least a part of the metal layer after the heating the substrate so as to convert the metal layer into the nitride silicide layer.
